(19) United States
(12) Patent Application Publication
(10) Pub. No.: US 2025/0194391 A1
(43) Pub. Date: Jun. 12, 2025

(54) DISPLAY DEVICE AND METHOD OF FABRICATING THE SAME

(71) Applicant: Samsung Display Co., LTD., Yongin-si (KR)

(72) Inventors: Keun Woo PARK, Yongin-si (KR); Tae Hoon KIM, Yongin-si (KR); Jae Cheol PARK, Yongin-si (KR)

(21) Appl. No.: 18/957,416

(22) Filed: Nov. 22, 2024

(30) Foreign Application Priority Data
Dec. 12, 2023 (KR) 10-2023-0179930

(51) Int. Cl. H10K 59/88; H10K 59/12; H10K 59/126; H10K 59/127; H10K 59/38; H10K 59/80

(52) U.S. Cl. CPC H10K 59/88; H10K 59/1201; H10K 59/126; H10K 59/127; H10K 59/38; H10K 59/877

(57) ABSTRACT

A display device includes: a first substrate including a display element layer; a second substrate facing the first substrate; and a sealing component between the first substrate and the second substrate, wherein the second substrate includes: a base layer including a display area overlapping the display element layer, and a non-display area enclosing the display area; a light blocking pattern in the non-display area of the base layer; a first dummy pattern between the light blocking pattern and the sealing component in the non-display area; a low-refractive layer in the non-display area and the display area, and interrupted by the first dummy pattern; and a second dummy pattern covering the first dummy pattern in the non-display area.

### CROSS-REFERENCE TO RELATED APPLICATION

The present application claims priority to and the benefit of Korean patent application number 10-2023-0179930, filed on Dec. 12, 2023, in the Korean Intellectual Property Office, the entire disclosure of which is incorporated herein by reference.

### BACKGROUND

### 1. Field

Aspects of some embodiments of the present disclosure relate to a display device and a method of fabricating the display device.

### 2. Description of Related Art

Recently, as interest in information display increases, research and development on display devices have been continuously conducted.

The above information disclosed in this Background section is only for enhancement of understanding of the background and therefore the information discussed in this Background section does not necessarily constitute prior art.

### SUMMARY

Various embodiments of the present disclosure may provide a display device having relatively improved reliability.

Furthermore, various embodiments of the present disclosure are directed to a method of fabricating the display device.

According to some embodiments of the present disclosure, a display device includes: a first substrate including a display element layer; a second substrate facing the first substrate; and a sealing component between the first substrate and the second substrate. According to some embodiments, the second substrate may include: a base layer including a display area overlapping the display element layer, and a non-display area enclosing the display area; a light blocking pattern positioned in the non-display area of the base layer; a first dummy pattern positioned between the light blocking pattern and the sealing component in the non-display area; a low-refractive layer positioned in the non-display area and the display area, and interrupted by the first dummy pattern; and a second dummy pattern covering the first dummy pattern in the non-display area.

According to some embodiments, the first dummy pattern may include an organic material.

According to some embodiments, the first dummy pattern may have a shape protruding from the light blocking pattern in a direction toward the sealing component.

According to some embodiments, the first dummy pattern may include a plurality of first dummy patterns.

According to some embodiments, the low-refractive layer may be positioned between the first dummy patterns adjacent to each other in the non-display area.

According to some embodiments, the second substrate may further include: a bank in the display area, and including a plurality of openings therein; and a color conversion pattern positioned in at least one opening of the openings, and a light scattering pattern positioned in another opening among the openings. According to some embodiments, the second dummy pattern may include a material identical to the bank.

According to some embodiments, the first dummy pattern may include a material identical to the light scattering pattern.

According to some embodiments, each of the first dummy pattern and the light scattering pattern may include base resin in which scattering particles are located.

According to some embodiments, the first dummy pattern may be in a layer different from the light scattering pattern.

According to some embodiments, the second substrate may further include: a first capping layer on the first dummy pattern and the low-refractive layer in a direction toward the sealing component; and a second capping layer on the second dummy pattern, the first capping layer, and the bank in the direction toward the sealing component.

According to some embodiments, each of the first capping layer and the second capping layer may include an inorganic material.

According to some embodiments, the base layer may include a dummy pixel area adjacent to the display area and corresponding to at least one area of the non-display area.

According to some embodiments, the second substrate may further include a color filter layer positioned in the display area and the non-display area and between the low-refractive layer and the base layer. According to some embodiments, the color filter layer may include a first color filter, a second color filter, and a third color filter.

According to some embodiments, in the non-display area, the first color filter, the second color filter, and the third color filter may be stacked on top of one another to form the light blocking pattern.

According to some embodiments, the display device may further include a filling layer between the first substrate and the second substrate. According to some embodiments, the filling layer may extend from the display area to the non-display area and have at least a portion covered with the sealing component.

According to some embodiments, the display element layer may include: a transistor on a substrate, and corresponding to the display area; and a light emitting element on the transistor, and including an emission layer.

According to some embodiments of the present disclosure may provide a method of fabricating a display device, including: forming a first substrate including a display element layer; forming a second substrate facing the first substrate; and bonding the first substrate and the second substrate to each other by a sealing component. According to some embodiments, the second substrate may include: a base layer including a display area overlapping the display element layer, and a non-display area enclosing the display area; a light blocking pattern positioned in the non-display area of the base layer; a first dummy pattern positioned between the light blocking pattern and the sealing component in the non-display area; a low-refractive layer positioned in the non-display area and the display area, and interrupted by the first dummy pattern; an optical layer in the display area, and including: a bank in the display area, and including a plurality of openings therein; and a color conversion pattern positioned in at least one opening among the openings, and a light scattering pattern positioned in another opening among the openings; and a second dummy pattern covering the first dummy pattern in the non-display area.

According to some embodiments, the first dummy pattern may include an organic material. According to some embodiments, the second dummy pattern may include a material identical to the bank.

According to some embodiments, forming the second substrate may include: forming a first color filter, a second color filter, and a third color filter on one surface of the base layer in the display area, and forming the light blocking pattern on the one surface of the base layer in the non-display area; forming the first dummy pattern on the light blocking pattern; forming the low-refractive layer on the first dummy pattern and the first to the third color filters; forming a first capping layer on the low-refractive layer and the first dummy pattern; forming the second dummy pattern on the first capping layer on the first dummy pattern, and forming the bank on the first capping layer in the display area; respectively forming the color conversion pattern and the light scattering pattern in the corresponding openings among the openings of the bank; and forming a second capping layer on the second dummy pattern, the bank the color conversion pattern, the light scattering pattern, and the first capping layer.

### BRIEF DESCRIPTION OF DRAWINGS

FIG. 1 is a schematic plan view illustrating a display device according to some embodiments.

FIG. 2 is a schematic cross-sectional view illustrating the display device of FIG. 1.

FIG. 3 is a circuit diagram schematically illustrating an electrical connection relationship of components included in a sub-pixel illustrated in FIG. 1.

FIG. 4 is a schematic plan view illustrating aspects of one of pixels of FIG. 1 according to some embodiments.

FIG. 5 is a schematic cross-sectional view taken along the line II-II′ of FIG. 4.

FIG. 6 is a schematic cross-sectional view illustrating aspects of an emission structure included in one of first to third light emitting elements of FIG. 5 according to some embodiments.

FIGS. 7 to 10 are schematic cross-sectional views taken along the line I-I′ of FIG. 1.

FIGS. 11 to 19 are schematic cross-sectional views illustrating a method of forming a second substrate of FIG. 7.

### DETAILED DESCRIPTION

As the present disclosure allows for various changes and numerous embodiments, particular embodiments will be illustrated in the drawings and described in detail in the written description. However, this is not intended to limit the present disclosure to particular modes of practice, and it is to be appreciated that all changes, equivalents, and substitutes that do not depart from the technical scope of the present disclosure are encompassed in the present disclosure.

Throughout the disclosure, like reference numerals refer to like parts throughout the various figures and embodiments of the present disclosure. The sizes of elements in the accompanying drawings may be exaggerated for clarity of illustration. It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof. Furthermore, in case that a first part such as a layer, a film, a region, or a plate is located on a second part, the first part may be not only directly on the second part but a third part may intervene between them. In addition, in case that it is expressed that a first part such as a layer, a film, a region, or a plate is formed on a second part, the surface of the second part on which the first part is formed is not limited to an upper surface of the second part but may include other surfaces such as a side surface or a lower surface of the second part. To the contrary, in case that a first part such as a layer, a film, a region, or a plate is under a second part, the first part may be not only directly under the second part but a third part may intervene between them.

Aspects of some embodiments of the present disclosure are described in more detail with reference to the accompanying drawings in order to describe aspects of some embodiments of the present disclosure in more detail so that those having ordinary knowledge in the technical field to which the present disclosure pertains can easily practice embodiments according to the present disclosure. Furthermore, a singular form may include a plural form as long as it is not specifically mentioned in a sentence.

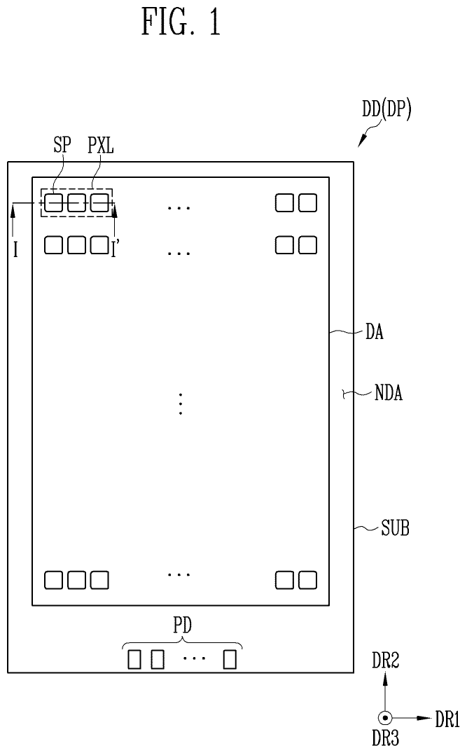

FIG. 1 is a schematic plan view illustrating a display device DD according to some embodiments.

In FIG. 1, for the sake of explanation, there is schematically illustrated the structure of the display device DD, for example, a display panel DP provided in the display device DD, centered on a display area DA formed to display an image.

Referring to FIG. 1, the display panel DP (or the display device DD) may include the display area DA and a non-display area NDA. The display panel DP may display an image through the display area DA. The non-display area NDA may be arranged around (e.g., in a periphery, or outside a footprint of) the display area DA.

The display panel DP may include a substrate SUB, sub-pixels SP, and pads PD.

The substrate SUB may include transparent insulating material to allow light transmission. The substrate SUB may be a rigid substrate or a flexible substrate.

For example, the rigid substrate may be one of a glass substrate, a quartz substrate, a glass ceramic substrate, and a crystalline glass substrate.

The flexible substrate may be either a film substrate or a plastic substrate which includes polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, or cellulose acetate propionate.

One area on the substrate SUB may be provided as the display area DA in which the sub-pixels SP (or pixels PXL) are located, and the other area on the substrate SUB may be provided as the non-display area NDA. For example, the substrate SUB may include the display area DA including a plurality of pixel areas in which the respective sub-pixels SP (or pixels PXL) are located, and the non-display area NDA arranged around the perimeter of (e.g., in a periphery or outside a footprint of) the display area DA (or adjacent to the display area DA).

The display area DA may have various shapes. For example, the display area DA may be provided in various forms or shapes in a plan view, such as a closed polygon including sides formed of linear lines, a circle, an ellipse or the like including a side formed of a curved line, and a semicircle, a semiellipse or the like including sides formed of a linear line and a curved line.

The non-display area NDA may be provided on at least one side of the display area DA. For example, the non-display area NDA may enclose the perimeter of the display area DA. The sub-pixels SP may be arranged on the substrate SUB in the form of a matrix (e.g., of rows and columns of sub-pixels SP) in a first direction DR1 and a second direction DR2 intersecting with the first direction DR1, but the arrangement of the sub-pixels SP is not limited thereto. For example, the sub-pixels SP may be arranged in a zigzag pattern in the first direction DR1 and the second direction DR2. For example, the first direction DR1 may refer to a row direction, and the second direction DR2 may refer to a column direction.

Two or more sub-pixels SP among the plurality of sub-pixels SP may form one pixel PXL, but embodiments according to the present disclosure are not limited thereto.

Components for controlling the sub-pixels SP may be located in the non-display area NDA on the substrate SUB. For example, lines electrically connected to the sub-pixels SP may be located in the non-display area NDA. The lines may include, for example, gate lines, date lines, and the like.

A driver electrically connected to the sub-pixels SP to drive the sub-pixels SP may be located (or integrated) in the non-display area NDA of the display panel DP. Furthermore, the pads PD may be located in the non-display area NDA on the substrate SUB. The pads PD may be electrically connected to the sub-pixels SP through the lines. For example, the pads PD may be electrically connected to the sub-pixels SP through the data lines.

According to some embodiments, a circuit board may be electrically connected to the pads PD by a conductive adhesive component such as an anisotropic conductive film. The circuit board may be a flexible circuit board or flexible film that is made of flexible material. The driver may be mounted on the circuit board and be electrically connected to the pads PD.

According to some embodiments, the display panel DP may have a planar display surface. According to some embodiments, the display panel DP may have an at least partially rounded display surface. According to some embodiments, the display panel DP may be bendable, foldable, or rollable. In the aforementioned cases, the display panel DP and/or the substrate SUB may include materials having flexible properties.

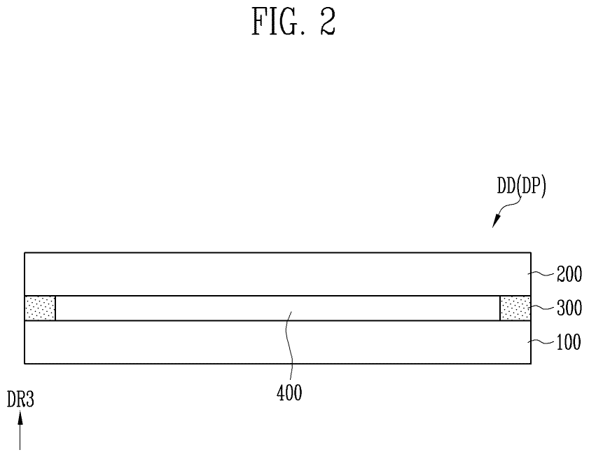

FIG. 2 is a schematic cross-sectional view illustrating the display device DD of FIG. 1.

Referring to FIGS. 1 and 2, the display device DD (or the display panel DP) may include a first substrate 100, a second substrate 200, and a sealing component 300. The sealing component 300 may couple the first substrate 100 and the second substrate 200 to each other. The first substrate 100 and the second substrate 200 may include the display area (refer to “DA” of FIG. 1) and the non-display area (refer to “NDA” of FIG. 1).

The first substrate 100 may include a plurality of sub-pixels (refer to “SP” of FIG. 1) {or pixels (refer to “PXL” of FIG. 1)} to display images. The sub-pixels SP may be located in the display area DA of the first substrate 100. Each of the sub-pixels SP (or the pixels PXL) may include a light emitting element configured to emit light, and a circuit element (or a driving element) configured to drive the light emitting element. For example, the light emitting element may be an organic light emitting diode, and the circuit element may be a transistor, but embodiments according to the present disclosure are not limited thereto.

The second substrate 200 may include an optical layer configured to selectively convert or transmit light emitted from the light emitting element. For example, the optical layer may be located in the display area DA of the second substrate 200, and may convert or transmit the wavelength of light emitted from the light emitting element of the first substrate 100 as it is.

The first substrate 100 and the second substrate 200 may be coupled to each other by the sealing component 300. The sealing component 300 may be located in the non-display area NDA between the first substrate 100 and the second substrate 200. For example, the sealing component 300 may not be located in the display area DA, and may be located in the non-display area NDA between the first substrate 100 and the second substrate 200 to enclose the display area DA. For example, the sealing component 300 may have various planar shapes according to the planar shapes of the first substrate 100 and/or the second substrate 200.

The sealing component 300 may include frit or the like. According to some embodiments, the sealing component 300 may include photocurable resin such as epoxy acrylate resin, polyester acrylate resin, urethane acrylate resin, polybutadiene acrylate resin, silicon acrylate resin, and alkyl acrylate resin. For example, laser light may be irradiated to the sealing component 300 applied between the first substrate 100 and the second substrate 200. The sealing component 300 may be cured by the laser light, thus sealing the first substrate 100 and the second substrate 200. According to some embodiments, the sealing component 300 may control the flow of monomers in an encapsulation layer included in the first substrate 100, thus defining a position at which the monomers are formed.

A filling layer 400 may be located in the display area DA between the first substrate 100 and the second substrate 200. The filling layer 400 may perform a shock absorption function for external pressure applied to the display device DD (or the display panel DP), but embodiments according to the present disclosure are not limited thereto. The filling layer 400 may maintain a gap between the first substrate 100 and the second substrate 200. The filling layer 400 may extend from the display area DA to the non-display area NDA between the first substrate 100 and the second substrate 200 and have at least a portion covered with the sealing component 300, thus meeting (or contacting) the sealing component 300.

The filling layer 400 may include material allowing light to pass therethrough. For example, the filling layer 400 may include organic material such as silicon resin, epoxy resin, or epoxy-acrylic resin. Furthermore, the filling layer 400 may include appropriate material for refractive index matching.

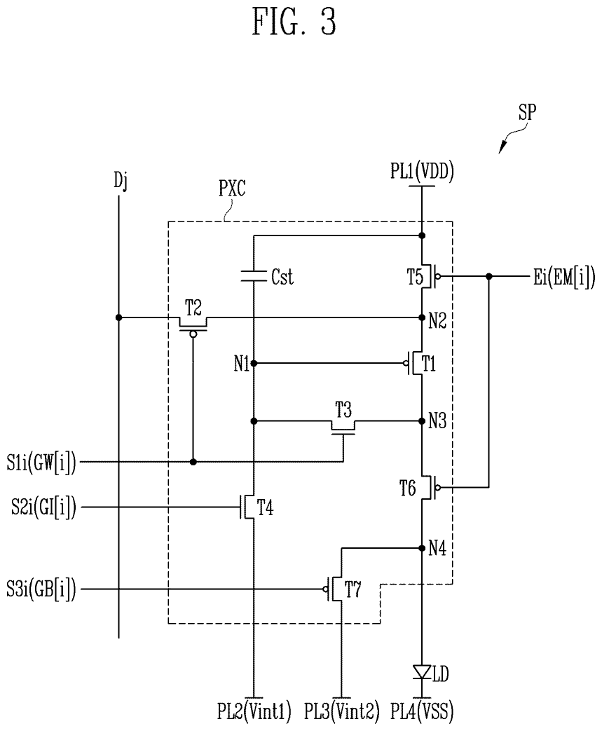

FIG. 3 is a circuit diagram schematically illustrating an electrical connection relationship of components included in the sub-pixel SP illustrated in FIG. 1. Although various components are illustrated in the sub-pixel SP in FIG. 3, embodiments according to the present disclosure are not limited thereto. For example, according to various embodiments, the sub-pixel SP may include additional components or fewer components without departing from the spirit and scope of embodiments according to the present disclosure. For convenience of description, FIG. 3 illustrates the sub-pixel SP that is positioned on an i-th horizontal line (or an i-th pixel row) and connected to a j-th data line Dj.

Referring to FIGS. 1 to 3, the sub-pixel SP may be positioned on the i-th horizontal line (or the i-th pixel row). The sub-pixel SP may include a pixel circuit PXC and a light emitting element LD. The pixel circuit PXC may include a first transistor T1, a second transistor T2, a third transistor T3, a fourth transistor T4, a fifth transistor T5, a sixth transistor T6, and a seventh transistor T7, and a storage capacitor Cst.

The light emitting element LD may include a first electrode electrically connected to a fourth node N4, and a second electrode electrically connected to a fourth power line PL4. The light emitting element LD may emit light of a certain luminance corresponding to the amount of current (or driving current) supplied from the first transistor T1. According to some embodiments, the light emitting element LD may be an organic light emitting diode including an organic light emitting layer.

The first transistor T1 (or a driving transistor) may be electrically connected between a first power line PL1 and the first electrode of the light emitting element LD. The first transistor T1 may include a gate electrode electrically connected to a first node N1. The first transistor T1 may control the amount of current (or driving current) flowing from the first power line PL1 to the fourth power line PL4 via the light emitting element LD, based on the voltage of the first node N1. A first power voltage VDD may be applied to the first power line PL1. A second power voltage VSS may be applied to the fourth power line PL4. The first power voltage VDD may be set to a voltage higher than the second power voltage VSS.

The second transistor T2 may be electrically connected between the j-th data line Dj and a second node N2. A gate electrode of the second transistor T2 may be electrically connected to a 1i-th scan line S1i (or a first scan line). In case that a first scan signal GW[i](e.g., a first scan signal of a low level) is supplied to the 1i-th scan line S1i, the second transistor T2 may be turned on to electrically connect the j-th data line Dj to the second node N2. If each of the first transistor T1 and the third transistor T3 is turned on, the second transistor T2 may transmit a data signal of the j-th data line Dj to the second node N2 in response to the first scan signal GW[i].

The third transistor T3 may be electrically connected between the first node N1 and a third node N3. A gate electrode of the third transistor T3 may be electrically connected to the 1i-th scan line S1i. The third transistor T3 may be turned on in case that the first scan signal GW[i] is supplied to the 1i-th scan line S1i. If the third transistor T3 is turned on, the first transistor T1 may have a diode-connected form.

The fourth transistor T4 may be electrically connected between the first node N1 and the second power line PL2. A gate electrode of the fourth transistor T4 may be electrically connected to a 2i-th scan line S2i (or a second scan line). A first initialization power voltage Vint1 may be applied to the second power line PL2. The fourth transistor T4 may be turned on in response to a second scan signal GI[i]. If the fourth transistor T4 is turned on, the first initialization power voltage Vint1 may be supplied to the first node N1 (i.e., the gate electrode of the first transistor T1).

The fifth transistor T5 may be electrically connected between the first power line PL1 and the second node N2. A gate electrode of the fifth transistor T5 may be electrically connected to an i-th emission control line Ei (or an emission control line). The sixth transistor T6 may be electrically connected between the third node N3 and the light emitting element LD (or the fourth node N4). A gate electrode of the sixth transistor T6 may be electrically connected to the i-th emission control line Ei. The fifth transistor T5 and the sixth transistor T6 may be turned off in case that an emission control signal EM[i](e.g., an emission control signal EM[i] of a high level) is supplied to the i-th emission control line Ei, and may be turned on in the other cases.

The seventh transistor T7 may be electrically connected between the first electrode (i.e., the fourth node N4) of the light emitting element LD and a third power line PL3. A gate electrode of the seventh transistor T7 may be electrically connected to a 3i-th scan line S3i (or a third scan line). A second initialization power voltage Vint2 may be applied to the third power line PL3. According to some embodiments, the second initialization power voltage Vint2 may be the same as or different from the first initialization power voltage Vint1. The seventh transistor T7 may be turned on by a third scan signal GB[i] supplied to the 3i-th scan line S3i to supply the second initialization power voltage Vint2 to the first electrode of the light emitting element LD.

The storage capacitor Cst may be connected or formed between the first power line PL1 and the first node N1.

According to some embodiments, the pixel circuit PXC may include a P-type transistor and an N-type transistor. The third transistor T3 and the fourth transistor T4 each may be formed of an oxide semiconductor transistor including an oxide semiconductor layer. For example, each of the third transistor T3 and the fourth transistor T4 may be formed of an N-type oxide semiconductor transistor, and include an oxide semiconductor layer as an active layer, but is not limited thereto. The oxide semiconductor transistor may be produced through a low-temperature process, and have low charge mobility compared to that of the polysilicon semiconductor transistor. In other words, the oxide semiconductor transistor may have excellent off-current characteristics. Therefore, leakage current between the third transistor T3 and the fourth transistor T4 may be minimized.

Each of the remaining transistors (e.g., the first, second, fifth, sixth, and seventh transistors T1, T2, T5, T6, and T7) other than the third and fourth transistors T3 and T4 may be formed of a polysilicon semiconductor transistor including a silicon semiconductor, and may include a polysilicon semiconductor layer as an active layer. For example, the active layer may be formed through a low-temperature polysilicon (LTPS) process. For example, the polysilicon semiconductor transistor may be a P-type polysilicon semiconductor transistor. Because a polysilicon semiconductor transistor has an advantage of a high response speed, the polysilicon semiconductor transistor may be applied to a switching element in which a high-speed switching operation is required.

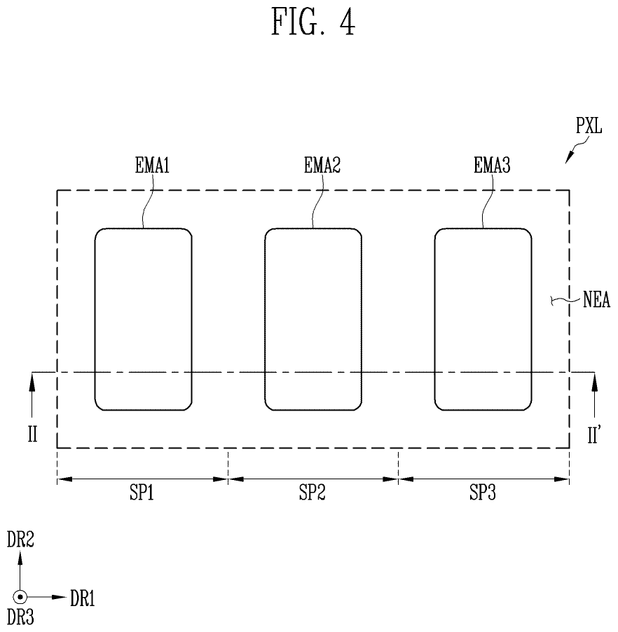

FIG. 4 is a schematic plan view illustrating aspects of one of the pixels PXL of FIG. 1 according to some embodiments.

Referring to FIGS. 1 to 4, the pixel PXL may include a first sub-pixel SP1, a second sub-pixel SP2, and a third sub-pixel SP3 that are arranged in the first direction DR1.

The first sub-pixel SP1 may include a first emission area EMA1 and a non-emission area NEA formed around the first emission area EMA1. The second sub-pixel SP2 may include a second emission area EMA2 and a non-emission area NEA formed around the second emission area EMA2. The third sub-pixel SP3 may include a third emission area EMA3 and a non-emission area NEA formed around the third emission area EMA3.

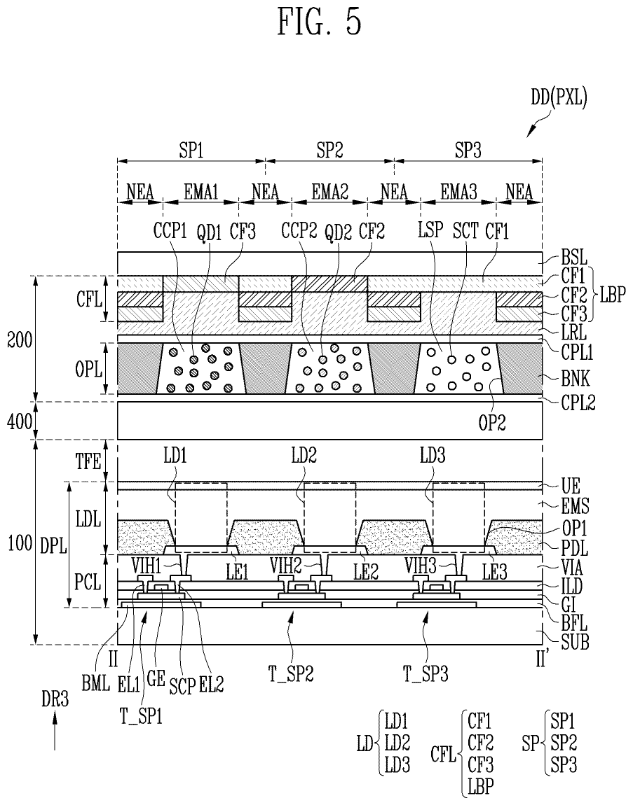

The first emission area EMA1 may be an area where light is emitted from a portion of an emission structure (refer to “EMS” of FIG. 5) that corresponds to the first sub-pixel SP1. The second emission area EMA2 may be an area where light is emitted from a portion of the emission structure EMS that corresponds to the second sub-pixel SP2. The third emission area EMA3 may be an area where light is emitted from a portion of the emission structure EMS that corresponds to the third sub-pixel SP3.

The first sub-pixel SP1, the second sub-pixel SP2, and the third sub-pixel SP3 may have substantially the same surface area, but are not limited thereto. According to some embodiments, the second sub-pixel SP2 may have a larger surface area than the first sub-pixel SP1. The third sub-pixel SP3 may have a larger surface area than the second sub-pixel SP2.

Each of the first sub-pixel SP1, the second sub-pixel SP2, and the third sub-pixel SP3 may have a polygonal shape. For example, each of the first sub-pixel SP1, the second sub-pixel SP2, and the third sub-pixel SP3 may have a rectangular shape or a hexagonal shape, but is not limited thereto. According to some embodiments, each of the first sub-pixel SP1, the second sub-pixel SP2, and the third sub-pixel SP3 may have a circular shape, a semi-elliptical shape, and so on.

The arrangement of the sub-pixels shown in FIG. 4 is an illustrative example, and embodiments of the present disclosure are not limited thereto. Each pixel PXL may include two or more sub-pixels, and the sub-pixels may be arranged in various ways. Each of the sub-pixels may have various shapes. Each of the emission areas of the sub-pixels may also have various shapes.

FIG. 5 is a schematic cross-sectional view taken along the line II-II′ of FIG. 4.

For the convenience of description, in FIG. 5, there is simply illustrated the cross-sectional structure (or stacked structure) of the display device DD centered on the pixel PXL formed on the substrate SUB, and a thickness direction of the substrate SUB is indicated in a third direction DR3.

Referring to FIGS. 1 to 5, the display device DD may include at least one or more pixels PXL located in the display area DA. The pixel PXL may be provided in a pixel area of the display area DA.

The pixel PXL may include at least one or more sub-pixels SP. For example, the pixel PXL may include a first sub-pixel SP1, a second sub-pixel SP2, and a third sub-pixel SP3. According to some embodiments, the first sub-pixel SP1 may be a green sub-pixel, the second sub-pixel SP2 may be a red sub-pixel, and the third sub-pixel SP3 may be a blue sub-pixel, but embodiments according to the present disclosure are not limited thereto. In the following embodiments, the term “sub-pixel SP” or “sub-pixels SP” will be used to collectively designate the first sub-pixel SP1, the second sub-pixel SP2, and the third sub-pixel SP3.

Each of the first, second, and third sub-pixels SP1, SP2, and SP3 may include the first substrate 100 and the second substrate 200. The filling layer 400 may be located between the first substrate 100 and the second substrate 200.

The first substrate 100 may include a substrate SUB, a display element layer DPL, and an encapsulation layer TFE. The display element layer DPL may include a pixel circuit layer PCL, and a light-emitting-element layer LDL.

The substrate SUB may include transparent insulating material to allow light transmission. The substrate SUB may be a rigid substrate or a flexible substrate.

The pixel circuit layer PCL and the light-emitting-element layer LDL may be arranged to overlap each other on one surface of the substrate SUB.

At least one or more insulating layers may be located in the pixel circuit layer PCL. For example, the insulating layers may include a buffer layer BFL, a gate insulating layer GI, an interlayer insulating layer ILD, and a via layer VIA which are successively stacked on the substrate SUB in the third direction DR3. The insulating layers located in the pixel circuit layer PCL are not limited to the aforementioned embodiments, and other insulating layers may be added, or some insulating layers may be omitted.

The buffer layer BFL may be arranged on the overall surface of the substrate SUB. The buffer layer BFL may prevent or reduce diffusion of impurities into circuit elements (or driving elements) constituting the pixel circuit PXC, for example, transistors. The buffer layer BFL may be an inorganic insulating layer including inorganic material (or substance). The buffer layer BFL may include at least one of silicon nitride (SiNₓ), silicon oxide (SiOₓ), silicon oxynitride (SiOₓN_{y}), or aluminum oxide (AlOₓ). Although the buffer layer BFL may be provided in a single-layer structure, the buffer layer BFL may be provided in a multilayer structure having at least two or more layers. In the case where the buffer layer BFL has a multilayer structure, the respective layers may be formed of the same material or different materials. The buffer layer BFL may be omitted depending on the material of the substrate SUB or processing conditions.

The gate insulating layer GI may be located on the overall surface of the buffer layer BFL. The gate insulating layer GI may include the same material as that of the buffer layer BFL, or include one or more suitable (or selected) materials among the materials mentioned (or illustrated) as the constituent materials of the buffer layer BFL. For example, the gate insulating layer GI may be an inorganic insulating layer including inorganic material.

The interlayer insulating layer ILD may be provided and/or formed on the overall surface of the gate insulating layer GI. The interlayer insulating layer ILD may include the same material as that of the buffer layer BFL, or include one or more suitable (or selected) materials among the materials mentioned (or illustrated) as the constituent materials of the buffer layer BFL.

The via layer VIA may be provided and/or formed on the overall surface of the interlayer insulating layer ILD. The via layer VIA may be an inorganic insulating layer including inorganic material or an organic insulating layer including organic material (or substance). The inorganic insulating layer may include, for example, at least one of silicon oxide (SiOₓ), silicon nitride (SiNₓ), silicon oxynitride (SiOₓN_{y}), or aluminum oxide (AlOₓ). For example, the organic insulating layer may include at least one of acrylic resin, epoxy resin, phenol resin, polyamide resin, polyimide resin, unsaturated polyester resin, polyphenylene ether resin, polyphenylene sulfide resin, or a benzocyclobutene resin. According to some embodiments, the via layer VIA may be formed of an organic insulating layer including organic material.

The via layer VIA may be partially open to include a via hole. The via hole may be a connection point for electrically connecting the pixel circuit PXC of the sub-pixel SP with the light emitting element LD.

The respective circuit elements (or driving elements) of the first to third sub-pixels SP1 to SP3 may be located in the pixel circuit layer PCL. For example, a transistor T_SP1 of the first sub-pixel SP1, a transistor T_SP2 of the second sub-pixel SP2, and a transistor T_SP3 of the third sub-pixel SP3 may be located in the pixel circuit layer PCL. The transistor T_SP1 of the first sub-pixel SP1 may be one of the transistors included in the pixel circuit PXC of the first sub-pixel SP1. The transistor T_SP2 of the second sub-pixel SP2 may be one of the transistors included in the pixel circuit PXC of the second sub-pixel SP2. The transistor T_SP3 of the third sub-pixel SP3 may be one of the transistors included in the pixel circuit PXC of the third sub-pixel SP3. In FIG. 5, one of the transistors of each sub-pixel SP is illustrated for the sake of clear and concise explanation, and the remaining circuit elements are omitted.

The transistor T_SP1 of the first sub-pixel SP1 may include a semiconductor pattern SCP, a gate electrode GE, a first terminal EL1, and a second terminal EL2.

The gate electrode GE may be located on the gate insulating layer GI and covered with the interlayer insulating layer ILD. For example, the gate electrode GE may be a gate conductive layer located between the gate insulating layer GI and the interlayer insulating layer ILD. The gate electrode GE may overlap a portion of the semiconductor pattern SCP. For example, the gate electrode GE may overlap an active pattern of the semiconductor pattern SCP.

The semiconductor pattern SCP may be provided and/or formed on the buffer layer BFL. The semiconductor pattern SCP may be a semiconductor layer formed of polysilicon, amorphous silicon, an oxide semiconductor, etc. The semiconductor pattern SCP may include an active pattern, a first contact area, and a second contact area. Each of the active pattern, the first contact area, and the second contact area may be formed of a semiconductor layer that is doped with no impurity or doped with an impurity. For example, each of the first contact area and the second contact area may be formed of a semiconductor layer that is doped with an impurity, and the active pattern may be configured of an undoped semiconductor layer.

The active pattern of the semiconductor pattern SCP may be an area that overlaps the gate electrode GE, and may be a channel area. The first contact area of the semiconductor pattern SCP may contact one end of the active pattern. The first contact area may be electrically connected to the first terminal EL1. The second contact area of the semiconductor pattern SCP may contact a remaining end of the active pattern. The second contact area may be electrically connected to the second terminal EL2.

The first terminal EL1 may be provided and/or formed on the interlayer insulating layer ILD. For example, the first terminal EL1 may be formed of a source-drain conductive layer formed between the interlayer insulating layer ILD and the via layer VIA. The first terminal EL1 may contact the first contact area of the semiconductor pattern SCP through a contact hole that passes through the gate insulating layer GI and the interlayer insulating layer ILD.

The second terminal EL2 may be provided and/or formed on the interlayer insulating layer ILD and spaced apart from the first terminal EL1. The second terminal EL2 may be formed of a source-drain conductive layer formed between the interlayer insulating layer ILD and the via layer VIA. The second terminal EL2 may contact the second contact area of the semiconductor pattern SCP through a contact hole that passes through the gate insulating layer GI and the interlayer insulating layer ILD.

A bottom metal pattern BML may be located under the transistor T_SP1 of the first sub-pixel SP1.

The bottom metal pattern BML may be a first conductive layer located between the substrate SUB and the buffer layer BFL. According to some embodiments, the bottom metal pattern BML may be electrically connected to the transistor T_SP1 of the first sub-pixel SP1, thus increasing a driving range of a voltage supplied to the gate electrode GE.

As the gate electrode GE, the first terminal EL1, and the second terminal EL2 are electrically connected to other circuit elements and/or lines, the transistor T_SP1 of the first sub-pixel SP1 may be provided as one of the transistors that constitute the pixel circuit PXC of the first sub-pixel SP1.

Each of the transistor T_SP2 of the second sub-pixel SP2 and the transistor T_SP3 of the third sub-pixel SP3 may have the same (or substantially the same) configuration as the transistor T_SP1 of the first sub-pixel SP1.

As described above, the pixel circuit layer PCL may include respective circuit elements of the first to third sub-pixels SP1 to SP3.

The light-emitting-element layer LDL may be located on the pixel circuit layer PCL. The light-emitting-element layer LDL may include a first lower electrode LE1, a second lower electrode LE2, a third lower electrode LE3, a pixel defining layer PDL, an emission structure EMS, and an upper electrode UE.

The first to third lower electrodes LE1 to LE3 may be respectively arranged in the first to third sub-pixels SP1 to SP3 on the pixel circuit layer PCL (or the via layer VIA). For example, the first lower electrode LE1 may be located on the via layer VIA of the first sub-pixel SP1, the second lower electrode LE2 may be located on the via layer VIA of the second sub-pixel SP2, and the third lower electrode LE3 may be located on the via layer VIA of the third sub-pixel SP3.

Each of the first to third lower electrodes LE1 to LE3 may be electrically connected to a circuit element located in the pixel circuit layer PCL through a corresponding via hole passing through the via layer VIA. For example, the first lower electrode LE1 may be electrically connected to the transistor T_SP1 of the first sub-pixel SP1 through a first via hole VIH1 passing through the via layer VIA. The second lower electrode LE2 may be electrically connected to the transistor T_SP2 of the second sub-pixel SP2 through a second via hole VIH2 passing through the via layer VIA. The third lower electrode LE3 may be electrically connected to the transistor T_SP3 of the third sub-pixel SP3 through a third via hole VIH3 passing through the via layer VIA.

According to some embodiments, each of the first lower electrode LE1, the second lower electrode LE2, and the third lower electrode LE3 may be an anode electrode. The first to third lower electrodes LE1 to LE3 may respectively have shapes similar to the first to third emission areas EMA1 to EMA3 of FIG. 4 when viewed in the third direction DR3. For example, the first lower electrode LE1 may have a shape similar to the first emission area EMA1 when viewed in the third direction DR3. The second lower electrode LE2 may have a shape similar to the second emission area EMA2 when viewed in the third direction DR3. The third lower electrode LE3 may have a shape similar to the third emission area EMA3 when viewed in the third direction DR3. However, embodiments of the present disclosure are not limited thereto.

Each of the first to third lower electrodes LE1 to LE3 may be electrically connected to the corresponding pixel circuit PXC to receive driving current. The first to third lower electrodes LE1 to LE3 may include opaque conductive material to reflect light, but embodiments according to the present disclosure are not limited thereto. According to some embodiments, the first to third lower electrodes LE1 to LE3 may include transparent conductive material.

The pixel defining layer PDL may be positioned on the first to third lower electrodes LE1 to LE3. The pixel defining layer PDL may include first openings OP1 which respectively expose a portion of the first lower electrode LE1, a portion of the second lower electrode LE2, and a portion of the third lower electrode LE3. The pixel defining layer PDL may be a structure for defining (or partitioning) the respective emission areas of the first to third sub-pixels SP1 to SP3. For example, the pixel defining layer PDL may define the first emission area EMA1 of the first sub-pixel SP1, the second emission area EMA2 of the second sub-pixel SP2, and the third emission area EMA3 of the third sub-pixel SP3.

The pixel defining layer PDL may be configured of an organic insulating layer including organic material. The organic material may include acrylic resin, epoxy resin, phenol resin, polyamide resin, polyimide resin, and the like. According to some embodiments, the pixel defining layer PDL may include light absorbing material or be coated with light absorbent, so that the pixel defining layer PDL can function to absorb light introduced from the outside. For example, the pixel defining layer PDL may include carbon-based black pigment. However, embodiments are not limited to the aforementioned example.

The pixel defining layer PDL may protrude from the via layer VIA in the third direction DR3.

The emission structure EMS may be located on the first to third lower electrodes LE1 to LE3 exposed through the first openings OP1 of the pixel defining layer PDL. The emission structure EMS may include an emission layer configured to generate light, an electron transport component configured to transport electrons, and a hole transport component configured to transport holes, but is not limited thereto.

According to some embodiments, the emission structure EMS may fill the first openings OP in the pixel defining layer PDL and be arranged over the pixel defining layer PDL, but embodiments according to the present disclosure are not limited thereto. The emission structure EMS may be formed through a process such as vacuum deposition, or inkjet printing.

The emission structure EMS may be located on the upper electrodes UE. According to some embodiments, the upper electrode UE may be a cathode electrode. The upper electrode UE may be a common layer provided in common to the first to third sub-pixels SP1 to SP3. The upper electrode UE may be provided in the form of a plate in the overall area of the display area DA. The upper electrode UE may function as a half mirror, partially transmitting and partially reflecting light emitted from the emission structure EMS.

The upper electrode UE may be a thin-film metal layer having a thickness allowing light emitted from the emission structure EMS to pass therethrough. The upper electrode UE may be made of a metal material having a relatively small thickness, or a transparent conductive material. According to some embodiments, the upper electrode UE may include at least one of various transparent conductive materials including indium tin oxide, indium zinc oxide, indium tin zinc oxide, aluminum zinc oxide, gallium zinc oxide, zinc tin oxide, or gallium tin oxide. According to some embodiments, the upper electrode UE may include at least one of magnesium, silver, or a compound thereof. However, the material of the upper electrode UE is not limited to the foregoing embodiments.

The first lower electrode LE1, the portion of the emission structure EMS that overlaps the first lower electrode LE1, the portion of the upper electrode UE that overlaps the first lower electrode LE1 may form a first light emitting element LD1. The second lower electrode LE2, the portion of the emission structure EMS that overlaps the second lower electrode LE2, the portion of the upper electrode UE that overlaps the second lower electrode LE2 may form a second light emitting element LD2. The third lower electrode LE3, the portion of the emission structure EMS that overlaps the third lower electrode LE3, the portion of the upper electrode UE that overlaps the third lower electrode LE3 may form a third light emitting element LD3.

The encapsulation layer TFE may be located on the upper electrode UE. The encapsulation layer TFE may cover the display element layer DPL. The encapsulation layer TFE may be configured to prevent or reduce contaminants such as oxygen and/or water or the like from penetrating into the light-emitting-element layer LDL. According to some embodiments, the encapsulation layer TFE may include a structure formed by alternately stacking one or more inorganic layers and one or more organic layers. For example, the inorganic layer may include, for example, silicon nitride, silicon oxide, or silicon oxynitride. For example, the organic film may include an organic insulating material such as acrylic resin, epoxy resin, phenol resin, polyamide resin, polyimide resin, unsaturated polyester resin, polyphenylene resin, polyphenylene sulfide resin, or benzocyclobute. However, the materials of the organic layer and the inorganic layer of the encapsulation layer TFE are limited to the aforementioned examples.

The second substrate 200 may be positioned over the first substrate 100 including the above-mentioned components. The second substrate 200 may face the first substrate 100 in the third direction DR3.

The second substrate 200 may include a base layer BSL, a color filter layer CFL, a low-refractive layer LRL, a first capping layer CPL1, an optical layer OPL, and a second capping layer CPL2.

The base layer BSL may be a rigid or flexible substrate, and the material or properties thereof are not particularly limited. The base layer BSL may be formed of the same material as that of the substrate SUB, or may be formed of material different from that of the substrate SUB. The base layer BSL may include the display area DA overlapping the display element layer DPL and the non-display area NDA enclosing the display area DA.

The color filter layer CFL may be located on one surface of the base layer BSL. The one surface of the base layer BSL may refer to a surface facing the first substrate 100. The color filter layer CFL may include a first color filter CF1, a second color filter CF2, a third color filter CF3, and a light blocking pattern LBP. The first color filter CF1 may be located on the one surface of the base layer BSL to correspond to the third emission area EMA3 of the third sub-pixel SP3. The second color filter CF2 may be located on the one surface of the base layer BSL to correspond to the second emission area EMA2 of the second sub-pixel SP2. The third color filter CF3 may be located on the one surface of the base layer BSL to correspond to the first emission area EMA1 of the first sub-pixel SP1.

The first color filter CF1, the second color filter CF2, and the third color filter CF3 may be arranged to overlap each other in the non-emission area NEA, thus functioning as the light blocking pattern LBP for preventing or reducing optical interference between adjacent sub-pixels SP from occurring. The light blocking pattern LBP may include the first color filter CF1, the second color filter CF2, and the third color filter CF3 that are sequentially stacked on the one surface of the base layer BSL. For example, the first color filter CF1 may be a blue color filter, the second color filter CF2 may be a red color filter, and the third color filter CF3 may be a green color filter, but the present disclosure is not limited thereto.

The low-refractive layer LRL may be located on the color filter layer CFL in a direction facing the first substrate 100. The low-refractive layer LRL (or referred to as a low-refractive index layer) may change, using a difference in refractive index in the display area DA, a path of light emitted from the optical layer OPL to the front direction (or the image display direction of the display device DD), thus enhancing frontal output light luminance.

The first capping layer CPL1 may be located on the low-refractive layer LRL. The first capping layer CPL1 may be located on the color filter layer CFL and cover the color filter layer CFL, thus protecting the color filter layer CFL. For example, the first capping layer CPL1 may be formed of an inorganic layer (or an inorganic insulating layer) including inorganic material.

The optical layer OPL may be located on the first capping layer CPL1 in the direction facing the first substrate 100. The optical layer OPL may include a bank BNK, a first color conversion pattern CCP1, a second color conversion pattern CCP2, and a light scattering pattern LSP.

The bank BNK may be configured to include at least one light blocking material and/or reflective material and enable light emitted from each of the first color conversion pattern CCP1, the second color conversion pattern CCP2, and the light scattering pattern LSP to more reliably travel in the image display direction of the display device DD, thus enhancing the light output efficiency of each sub-pixel SP. According to some embodiments, the bank BNK may prevent or reduce a light leakage defect in which light leaks between adjacent sub-pixels SP. According to some embodiments, the bank BNK may include transparent material (or substance). The transparent material may include, for example, polyamide resin, polyimide resin, and the like, but the present disclosure is not limited thereto. According to some embodiments, in order to enhance the efficiency of light emitted from each sub-pixel SP, a separate reflective material layer may be provided and/or formed on the bank BNK.

The bank BNK may include a second opening OP2 that exposes a portion of the first capping layer CPL1 in each of the first to third sub-pixels SP1 to SP3. For example, the bank BNK may include a second opening OP2 that exposes a portion of the first capping layer CPL1 in the first sub-pixel SP1, a second opening OP2 that exposes a portion of the first capping layer CPL1 in the second sub-pixel SP2, and a second opening OP2 that exposes a portion of the first capping layer CPL1 in the third sub-pixel SP3. The second opening OP2 of the bank BNK may correspond to the emission area EMA of each sub-pixel SP. For example, in the first sub-pixel SP1, the second opening OP2 of the bank BNK may correspond to the first emission area EMA1. In the second sub-pixel SP2, the second opening OP2 of the bank BNK may correspond to the second emission area EMA2. In the third sub-pixel SP3, the second opening OP2 of the bank BNK may correspond to the third emission area EMA3.

The bank BNK may be a structure to define locations of the first color conversion pattern CCP1, the second color conversion pattern CCP2, and the light scattering pattern LSP.

The first color conversion pattern CCP1 may be positioned in the second opening OP2 of the bank BNK of the first sub-pixel SP1 to correspond to the first light emitting element LD1. The first color conversion pattern CCP1 may include a plurality of first color conversion particles QD1 which are dispersed in a matrix material such as base resin. For example, the first color conversion particles QD1 may be green quantum dots, which absorb incident blue light, shift the wavelength of the light according to an energy transition, and emit green light. In this case, the first sub-pixel SP1 may be a green sub-pixel. The first color conversion pattern CCP1 may be located in at least the first emission area EMA1.

The second color conversion pattern CCP2 may be positioned in the second opening OP2 of the bank BNK of the second sub-pixel SP2 to correspond to the second light emitting element LD2. The second color conversion pattern CCP2 may include a plurality of second color conversion particles QD2 which are dispersed in a matrix material such as base resin. For example, the second color conversion particles QD2 may be red quantum dots, which absorb incident blue light, shift the wavelength of the light according to an energy transition, and emit red light. In this case, the second sub-pixel SP2 may be a red sub-pixel. The second color conversion pattern CCP2 may be located in at least the second emission area EMA2.

The light scattering pattern LSP may be positioned in the second opening OP2 of the bank BNK of the third sub-pixel SP3 to correspond to the third light emitting element LD3. The light scattering pattern LSP may include a plurality of light scattering particles SCT which are dispersed in a matrix material such as base resin. The light scattering pattern LSP may include light scattering particles SCT formed of material such as silica, but the constituent material of the light scattering particles SCT is not limited thereto. According to some embodiments, the light scattering particles SCT may be omitted, and the light scattering pattern LSP formed of a transparent polymer may be provided. For example, the light scattering pattern LSP may transmit incident blue light in the image display direction. In this case, the third sub-pixel SP3 may be a blue sub-pixel. The light scattering pattern LSP may be located in at least the third emission area EMA3.

The second capping layer CPL2 may be located on the optical layer OPL in the direction facing the first substrate 100. The second capping layer CPL2 may be configured of an inorganic layer (or an inorganic insulating layer) including inorganic material. For example, the second capping layer CPL2 may include at least one of silicon nitride (SiNₓ), silicon oxide (SiOₓ), silicon oxynitride (SiOₓN_{y}), or metal oxide such as aluminum oxide (AlOₓ), but embodiments according to the present disclosure are not limited thereto. According to some embodiments, the second capping layer CPL2 may be formed of an organic insulating layer including organic material. The second capping layer CPL2 may be positioned on the optical layer OPL to protect the optical layer OPL from external water, oxygen, or the like, thus further enhancing the reliability of the optical layer OPL.

The filling layer 400 may be located in the display area DA between the first substrate 100 and the second substrate 200 having the aforementioned configuration. For example, the filling layer 400 may be located between the encapsulation layer TFE of the first substrate 100 and the second capping layer CPL2 of the second substrate 200. The filling layer 400 may maintain a gap between the first substrate 100 and the second substrate 200.

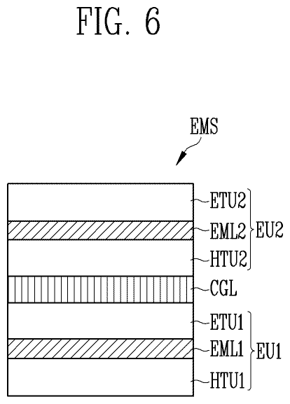

FIG. 6 is a schematic cross-sectional view illustrating aspects of the emission structure EMS included in one of the first to third light emitting elements LD1 to LD3 of FIG. 5 according to some embodiments.

Referring to FIGS. 5 and 6, the emission structure EMS may have a tandem structure in which a first emission component EU1 and a second emission component EU2 are stacked. The emission structure EMS may have a substantially identical configuration in each of the first to third light emitting elements LD1 to LD3 of FIG. 5.

Each of the first and second emission components EU1 and EU2 may include at least one emission layer configured to generate light in response to current applied thereto. The first emission component EU1 may include a first emission layer EML1, a first electron transport component ETU1, and a first hole transport component HTU1. The first emission layer EML1 may be located between the first electron transport component ETU1 and the first hole transport component HTU1. The second emission component EU2 may include a second emission layer EML2, a second electron transport component ETU2, and a second hole transport component HTU2. The second emission layer EML2 may be located between the second electron transport component ETU2 and the second hole transport component HTU2.

Each of the first and second hole transport components HTU1 and HTU2 may include at least one of a hole injection layer or a hole transport layer, and may further include a hole buffer layer, an electron blocking layer, and the like, as needed. The first and second hole transport components HTU1 and HTU2 may have the same configuration or have different configurations.

Each of the first and second electron transport components ETU1 and ETU2 may include at least one of an electron injection layer or an electron transport layer, and may further include an electron buffer layer, a hole blocking layer, and the like, as needed. The first and second electron transport components ETU1 and ETU2 may have the same configuration or have different configurations.

An intermediate layer (or connection layer) that may be provided in the form of a charge generation layer CGL may be located between the first emission component EU1 and the second emission component EU2, thus connecting the first emission component EU1 and the second emission component EU2 to each other. Hereinafter, the charge generation layer CGL will be referred to as an intermediate layer. According to some embodiments, the intermediate layer CGL may have a stacked structure including a p-dopant layer and an n-dopant layer. For example, the p-dopant layer may include a p-type dopant such as HAT-CN, TCNQ, or NDP-9, and the n-dopant layer may include alkali metal, alkaline earth metal, lanthanide metal, or a combination thereof. However, the structure (or material) of the intermediate layer CGL is not limited to the aforementioned embodiments. According to some embodiments, the intermediate layer CGL may include material with relatively high charge conductivity (or charge mobility) compared to the first and second emission components EU1 and EU2, thus having conductive properties.

According to some embodiments, the first emission layer EML1 and the second emission layer EML2 may generate light in different colors, but are not limited thereto. In some embodiments, the first emission layer EML1 and the second emission layer EML2 may generate light in the same color.

In the aforementioned embodiments, the emission structure EMS has been described as having a tandem structure including the first emission component EU1 and the second emission component EU2 that are stacked on top of one another, but the structure thereof is not limited thereto. According to some embodiments, the emission structure EMS may be configured of a tandem structure including three emission components stacked on top of one another.

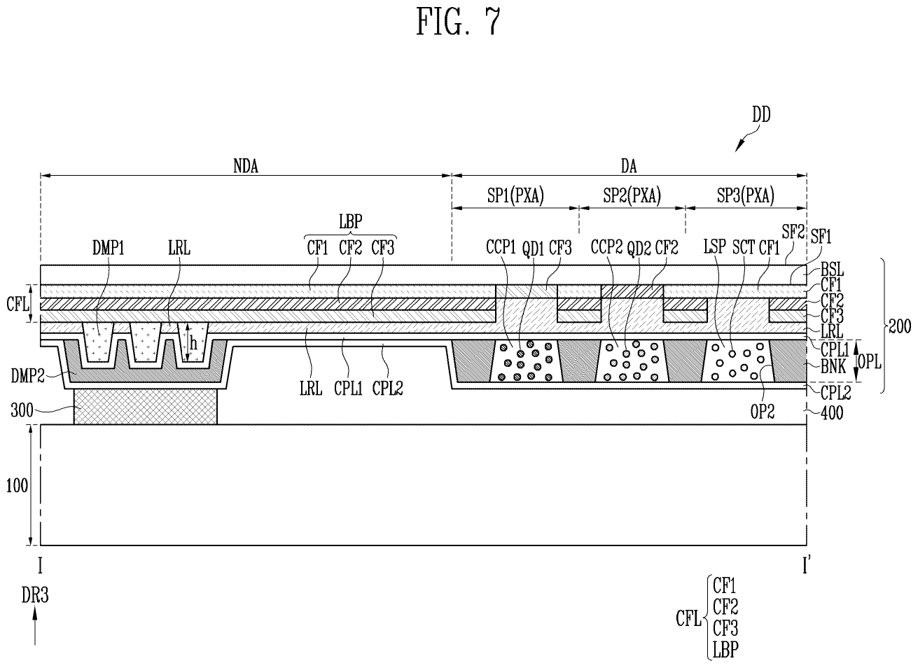

FIGS. 7 to 10 are schematic cross-sectional views taken along line I-I′ of FIG. 1.

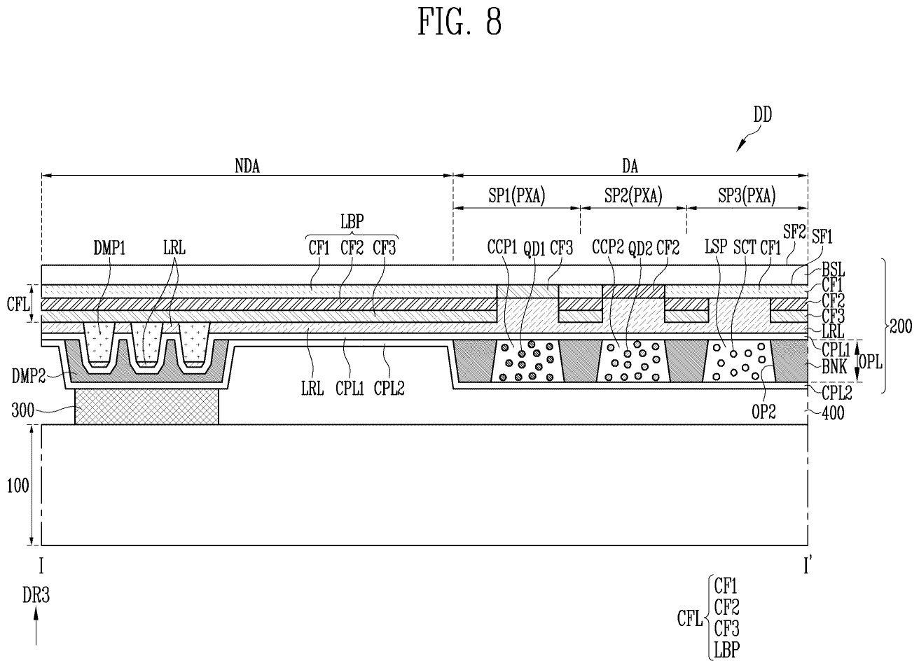

FIGS. 8 to 10 illustrate modified examples of FIG. 7 related to a first dummy pattern DMP1 and the like.

The following description related to embodiments of FIGS. 7 to 10 will be focused on differences from the above-mentioned embodiments so as to avoid redundant description.

Referring to FIGS. 1, and 7 to 10, the display device DD may include a first substrate 100 and a second substrate 200 connected to each other using a sealing component 300. A filling layer 400 may be located in the display area DA between the first substrate 100 and the second substrate 200. The filling layer 400 may extend to at least a portion of the non-display area NDA between the first substrate 100 and the second substrate 200, thus contacting the sealing component 300.

The display area DA may include a pixel area PXA. Each of the first to third sub-pixels SP1 to SP3 may be located in the pixel area PXA.

Hereinafter, the configuration of the second substrate 200 in the display area DA and the non-display area NDA will be described.

The second substrate 200 may include a base layer BSL, a color filter layer CFL, a low-refractive layer LRL, and an optical layer OPL. The base layer BSL, the color filter layer CFL, and the low-refractive layer LRL may be located in the display area DA and the non-display area NDA. The optical layer OPL may be located in the display area DA.

The base layer BSL may include a first surface SF1 and a second surface SF2 that face each other in the third direction DR3. The second surface SF2 may be positioned on the uppermost layer in the third direction DR3 to provide an input surface and/or a display surface to a user.

In the display area DA, the color filter layer CFL may be located on the first surface SF1 of the base layer BSL. A first capping layer CPL1 may be located on the color filter layer CFL. The optical layer OPL may be located on the first capping layer CPL1. A second capping layer CPL2 may be located on the optical layer OPL.

In the non-display area NDA, the color filter layer CFL may be located on the first surface SF1 of the base layer BSL. The color filter layer CFL may include a first color filter CF1 directly located on the first surface SF1 of the base layer BSL, a second color filter CF2 located on the first color filter CF1, and a third color filter CF3 located on the second color filter CF2. The first color filter CF1 may be a blue color filter that overlaps the third emission area (refer to “EMA3” of FIG. 5) and transmits blue light. The second color filter CF2 may be a red color filter that overlaps the second emission area (refer to “EMA2” of FIG. 5) and transmits red light. The third color filter CF3 may be a green color filter that overlaps the first emission area (refer to “EMA1” of FIG. 5) and transmits green light.

The first color filter CF1, the second color filter CF2, and the third color filter CF3 may be stacked on top of one another, thus forming a light blocking pattern LBP. The light blocking pattern LBP may be positioned over the overall area of the non-display area NDA. The light blocking pattern LBP may overlap the non-emission area (refer to “NEA” of FIG. 5) in the display area DA (or the pixel area PXA).

According to some embodiments, a first dummy pattern DMP1 may be located on the light blocking pattern LBP. The first dummy pattern DMP1 may be located on the light blocking pattern LBP positioned in the non-display area NDA to correspond the sealing component 300. The first dummy pattern DMP1 may be positioned between the light blocking pattern LBP and the sealing component 300 in the non-display area NDA.

The first dummy pattern DMP1 may block penetration of oxygen or water that may be drawn from the non-display area NDA to the display area DA, thus reducing or preventing or reducing damage to elements located in the display area DA, for example, the first to third sub-pixels SP1 to SP3. The first dummy pattern DMP1 may protrude in a direction from the light blocking pattern LBP (or the third color filter CF3) toward the first substrate 100 along a direction opposite to the third direction DR3. The first dummy pattern DMP1 may have a certain height (h) in the direction opposite to the third direction DR3. For example, the first dummy pattern DMP1 may have a height (h) ranging from approximately 3 μm to approximately 8 μm. A plurality of first dummy patterns DMP1 may be provided, but the present disclosure is not limited thereto. The first dummy patterns DMP1 that are adjacent to each other may be arranged to be spaced apart from each other.

The first dummy pattern DMP1 may include organic material including titanium dioxide in the form of nanoparticles, but is not limited thereto. According to some embodiments, the first dummy pattern DMP1 may include the same material as some components of the optical layer OPL. For example, the first dummy pattern DMP1 may include the same material as the light scattering pattern LSP including light scattering particles SCT.

The low-refractive layer LRL may be located on the color filter layer CFL. The low-refractive layer LRL (or referred to as a low-refractive index layer) may change, using a difference in refractive index in the display area DA, a path of light emitted from the optical layer OPL to the front direction (or the image display direction of the display device DD), thus enhancing frontal output light luminance. The low-refractive layer LRL may recycle light (e.g., blue-based light) that does not react with the first and second color conversion patterns CCP1 and CCP2 so that the light can react with the first and second color conversion patterns CCP1 and CCP2, whereby the output light luminance of the first and second color conversion patterns CCP1 and CCP2 can be increased.

The low-refractive layer LRL may include resin and hollow particles distributed in the resin and have a refractive index ranging from 1.1 to 1.3, but embodiments according to the present disclosure are not limited thereto. Here, the hollow particles may refer to particles each having a form in which space is present in a surface and/or interior of an organic or inorganic particle. The hollow particles may be hollow silica particles.

A portion of the low-refractive layer LRL may be separated from the other portion thereof by the first dummy pattern DMP1 in the non-display area NDA. In other words, the low-refractive layer LRL may include an interrupted portion (or an open portion) separated by the first dummy pattern DMP1. The interrupted portion may be defined as a portion of the low-refractive layer LRL disconnected from the other portion thereof due to the first dummy pattern DMP1 rather than being continuously formed on the sealing component 300 in the non-display area NDA. The low-refractive layer LRL may have a thickness ranging from 1 μm to 2 μm (or approximately 1 μm to approximately 2 μm) in the third direction DR3. The low-refractive layer LRL may be formed on the light blocking pattern LBP in the non-display area NDA by a known coating method or the like.

As the low-refractive layer LRL is applied on the first dummy pattern DMP1 having a height (h) greater (or thicker) than the thickness of the low-refractive layer LRL, the low-refractive layer LRL is not continuously formed by the shape of the first dummy pattern DMP1, and may have a separated interrupted portion. For example, the low-refractive layer LRL may be formed on the light blocking pattern LBP between the first dummy patterns DMP1 adjacent to each other in the direction facing the first substrate 100, and may not be formed on one surface of each of the first dummy patterns DMP1, for example, a lower surface facing the sealing component 300. However, the present disclosure is not limited to the aforementioned example. According to some embodiments, as illustrated in FIG. 8, the low-refractive layer LRL may also be formed on the one surface of the first dummy pattern DMP1. For example, depending on the height of the first dummy pattern DMP1, the low-refractive layer LRL may also be formed on the one surface of the first dummy pattern DMP1. In this case, the first dummy pattern DMP1 may have a height (h) ranging from approximately 3 μm to approximately 6 μm.

The low-refractive layer LRL formed of an organic layer (or an organic insulating layer) has advantages in terms of flexibility and elasticity, but may be vulnerable to penetration of water or oxygen, compared to an inorganic layer (or an inorganic insulating layer). Accordingly, the first dummy pattern DMP1 is formed so that the low-refractive index layer LRL can have an interrupted structure in the non-display area NDA in which the sealing component 300 is positioned, thus reducing or preventing or reducing contaminants such as external oxygen, water, and the like, which may be drawn into the display area DA from the outside of the sealing component 300 through the low-refractive layer LRL, thereby relatively improving the reliability of the first to third sub-pixels SP1 to SP3.

The first capping layer CPL1 may be located on the color filter layer CFL, the first dummy pattern DMP1, and the low-refractive layer LRL in the direction facing the first substrate 100 (i.e. a direction toward the sealing component 300). The first capping layer CPL1 may be formed of an inorganic insulating layer including inorganic material. A second dummy pattern DMP2 may be formed on the first capping layer CPL1 on the first dummy pattern DMP1.

The second dummy pattern DMP2 may cover at least a portion of the first dummy pattern DMP1 with the first capping layer CPL1 interposed therebetween. According to some embodiments, the second dummy pattern DMP2 may be formed of an organic layer (an organic insulating layer). For example, the second dummy pattern DMP2 may include the same material as the bank BNK. In this case, the second dummy pattern DMP2 may be formed in the same process as the bank BNK and include the same material as the bank BNK, and may be provided in the same layer as the bank BNK, but is not limited thereto. Each of the second dummy pattern DMP2 and the bank BNK may have a thickness, for example, approximately 10 μm, but is not limited thereto.

The second dummy pattern DMP2 may cover the first dummy pattern DMP1 in the direction facing the first substrate 100, thus having a planar surface mitigating a stepped portion caused by the first dummy patterns DMP1.

According to some embodiments, the second dummy pattern DMP2 may be formed on the first capping layer CPL1 to correspond to the sealing component 300, thus functioning as a shock absorber to mitigate force applied to the sealing component 300 during a process of bonding (or coupling) the first substrate 100 and the second substrate 200 to each other.

The second capping layer CPL2 may be located on the second dummy pattern DMP2, the first capping layer CPL1, and the bank BNK in the direction facing the first substrate 100 (i.e., the direction toward the sealing component 300). The second capping layer CPL2 may be configured of an inorganic layer (or an inorganic insulating layer) including inorganic material. The second capping layer CPL2 may completely cover the second dummy pattern DMP2, thus preventing or reducing the second dummy pattern DMP2 from being exposed to the outside. Consequently, a path along which oxygen, water, or the like is introduced through the second dummy pattern DMP2 in the non-display area NDA is blocked, whereby the reliability of the first to third sub-pixels SP1 to SP3 in the display area DA can be further enhanced.

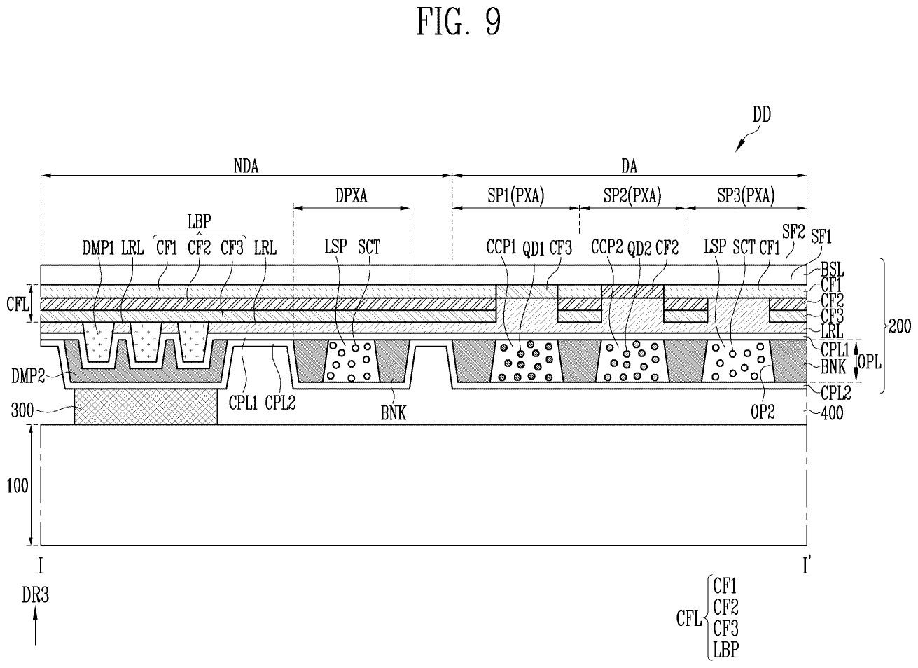

According to some embodiments, as illustrated in FIG. 9, the non-display area NDA may include a dummy pixel area DPXA in which a dummy pixel is located. The dummy pixel having a structure substantially identical or similar to the first to third sub-pixels SP1 to SP3 may be located in the dummy pixel area DPXA. The dummy pixel may be provided in an isolated shape in the dummy pixel area DPXA. The dummy pixel may be provided in the dummy pixel area DPXA (or the non-display area NDA) so as to prevent or reduce a defect attributable to a deviation from being caused during a fabricating process, and may be selectively provided depending on embodiments. The base layer BSL may include the dummy pixel area DPXA adjacent to the display area DA and corresponding to at least one area of the non-display area NDA.

In the dummy pixel area DPXA of the second substrate 200, the light blocking pattern LBP and the optical layer OPL located on the light blocking pattern LBP may be positioned.

The optical layer OPL may include a bank BNK, and a light scattering pattern LSP positioned between adjacent banks BNK. The bank BNK may be the same as the bank BNK positioned in the display area DA. The light scattering pattern LSP may be the same as the light scattering pattern LSP positioned in the display area DA. The light scattering pattern LSP may include light scattering particles SCT.

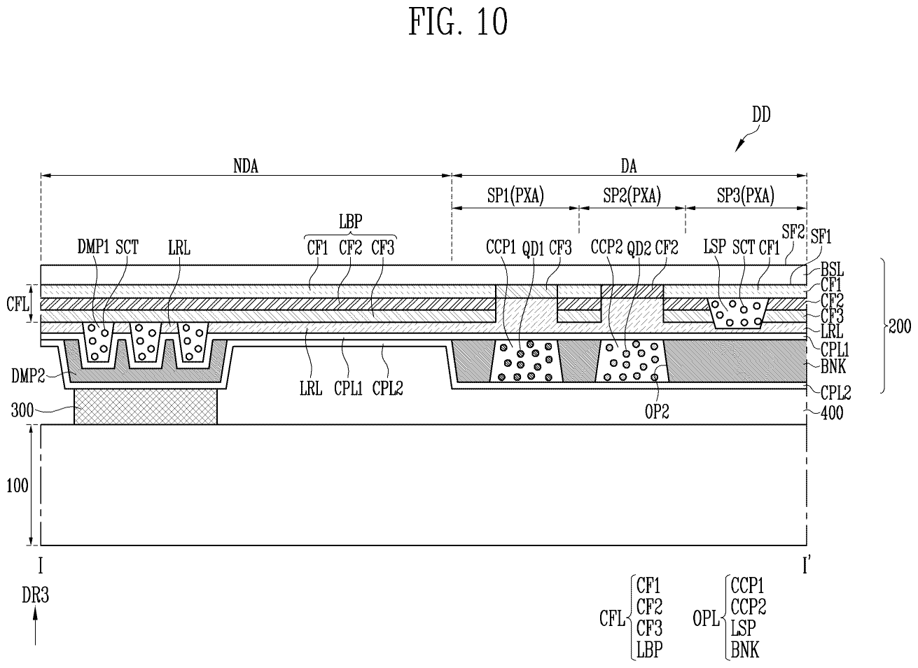

According to some embodiments, the first dummy pattern DMP1 may be formed through the same process as one component in the optical layer OPL positioned in the display area DA. For example, as illustrated in FIG. 10, the first dummy pattern DMP1 may be formed through the same process as the light scattering pattern LSP positioned in the third sub-pixel SP3 in the optical layer OPL. For example, the first dummy pattern DMP1 and the light scattering pattern LSP may be simultaneously or concurrently formed through a photolithography process using a mask. In this case, the first dummy pattern DMP1 and the light scattering pattern LSP may include the same material. For example, the first dummy pattern DMP1 and the light scattering pattern LSP may include a plurality of light scattering particles SCT which are dispersed in a certain matrix material such as base resin. Here, the light scattering pattern LSP positioned in the display area DA may be located on the first color filter CF1 to correspond to the third emission area EMA3 enclosed by the light blocking pattern LBP in the third sub-pixel SP3. In the third sub-pixel SP3, the bank BNK may be located on the light scattering pattern LSP and the light blocking pattern LBP with the low-refractive layer LRL interposed therebetween. According to another embodiment, the first dummy pattern DMP1 may be in a layer different from the light scattering patter LSP.

According to some embodiments, the first dummy pattern DMP1 may be located on the sealing component 300 in the non-display area NDA between the first substrate 100 and the second substrate 200. The first dummy pattern DMP1 may separate (or disconnect) a portion of the low-refractive layer LRL from the other portion thereof in the non-display area NDA, thus forming a discontinuity portion of the low-refractive layer LRL. Dividing the low-refractive layer LRL in the non-display area NDA into portions may reduce or block external oxygen, water, or the like from being drawn from the non-display area NDA into the display area DA through the low-refractive layer LRL. Accordingly, the reliability of the display device DD (or the first to third sub-pixels SP1 to SP3) may be relatively improved.

According to some embodiments, with respect to the direction facing the first substrate 100, in the non-display area NDA of the second substrate 200, the first capping layer CPL1 including inorganic material, the second dummy pattern DMP2 including organic material and located on the first capping layer CPL1, and the second capping layer CPL2 including inorganic material and located on the second dummy pattern DMP2 may be used as an encapsulation component identical to the encapsulation layer TFE of the first substrate 100. Due to the encapsulation component, external oxygen, water, or the like may be reduced or prevented from being drawn into the display area DA, whereby the reliability of the display device DD can be further relatively improved.

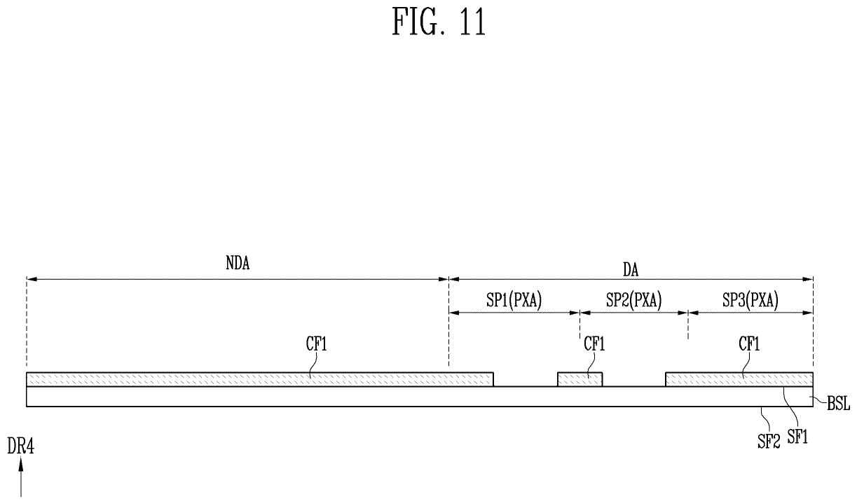

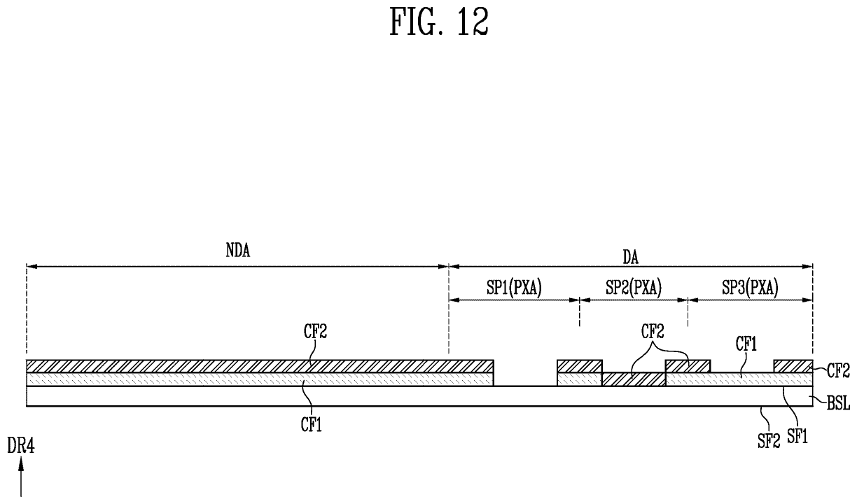

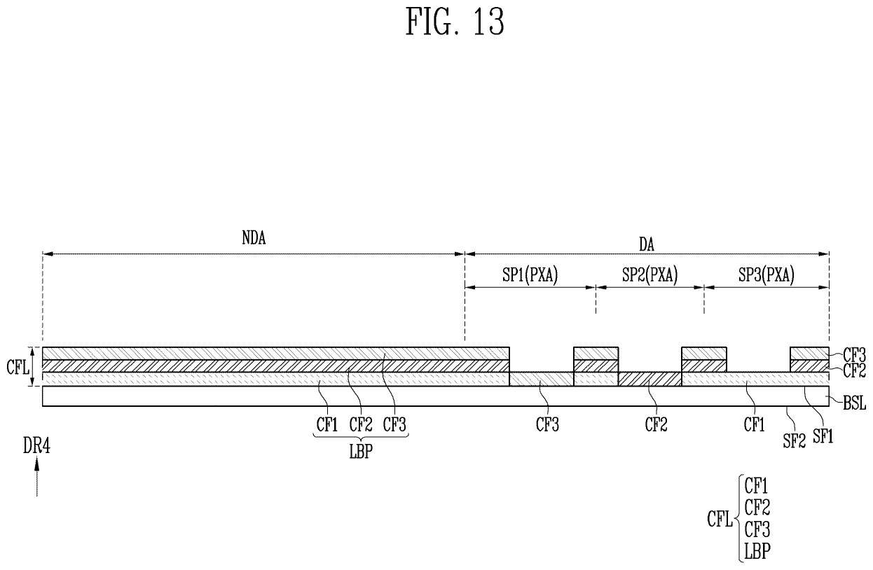

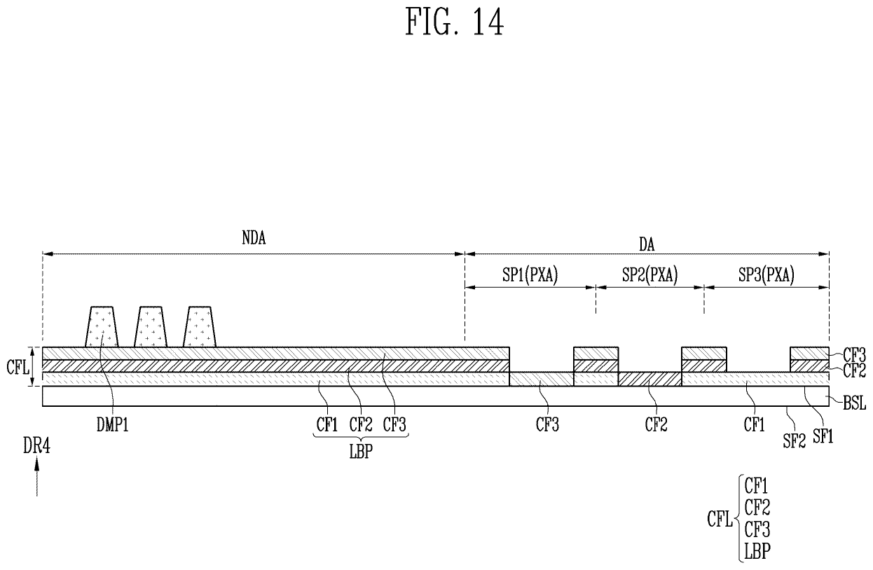

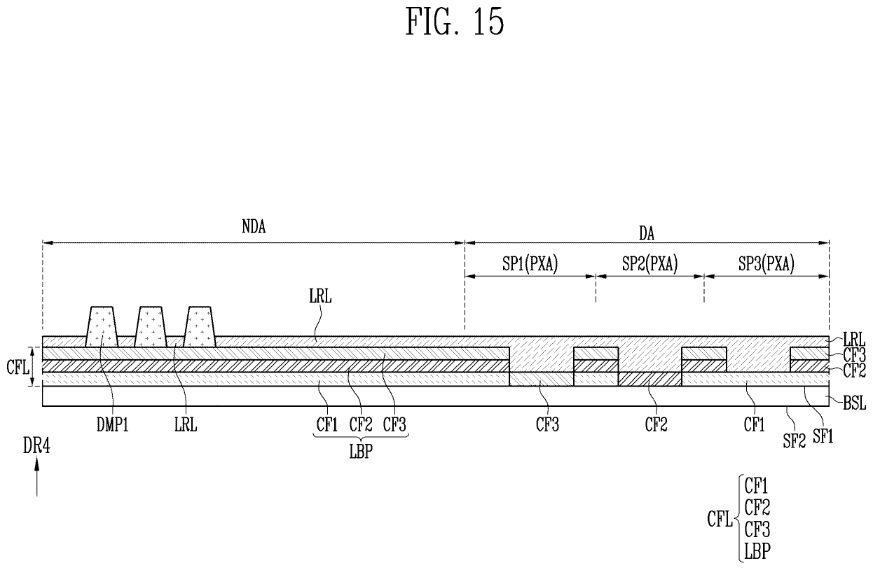

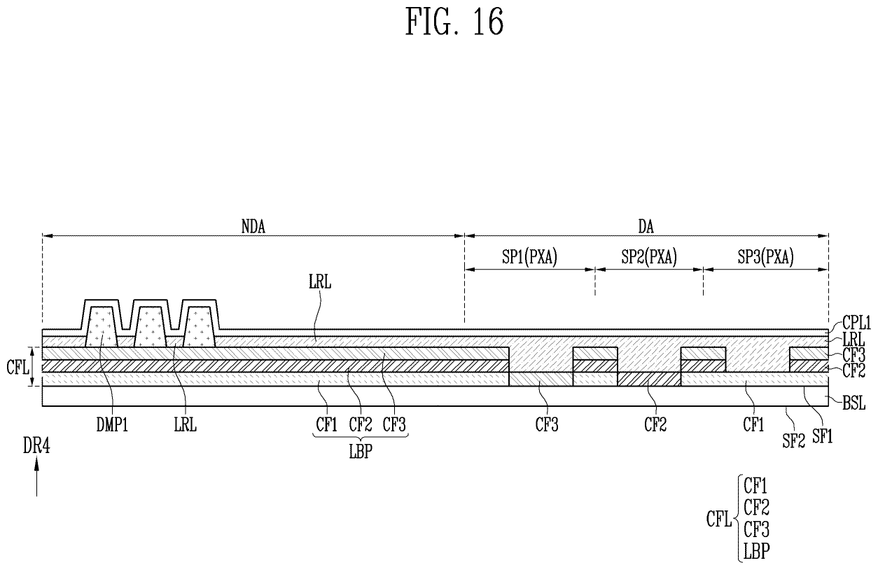

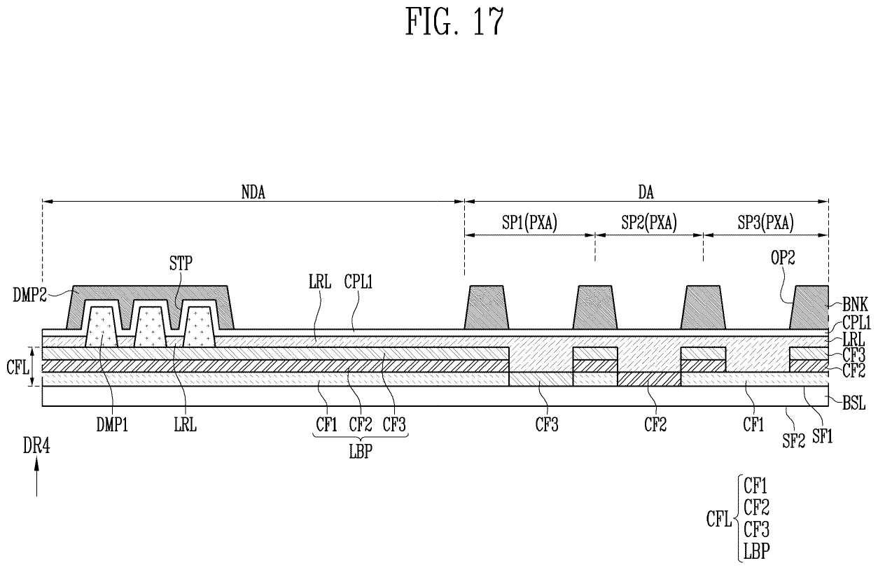

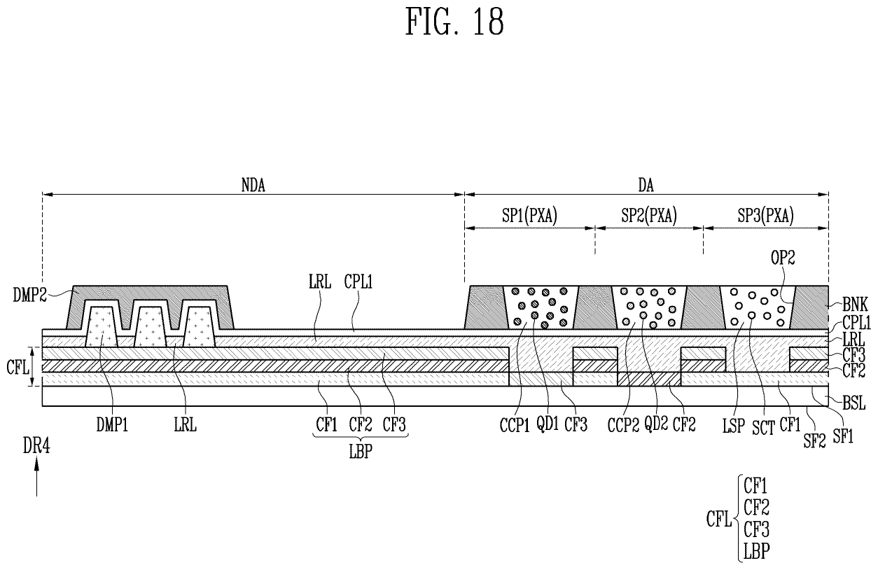

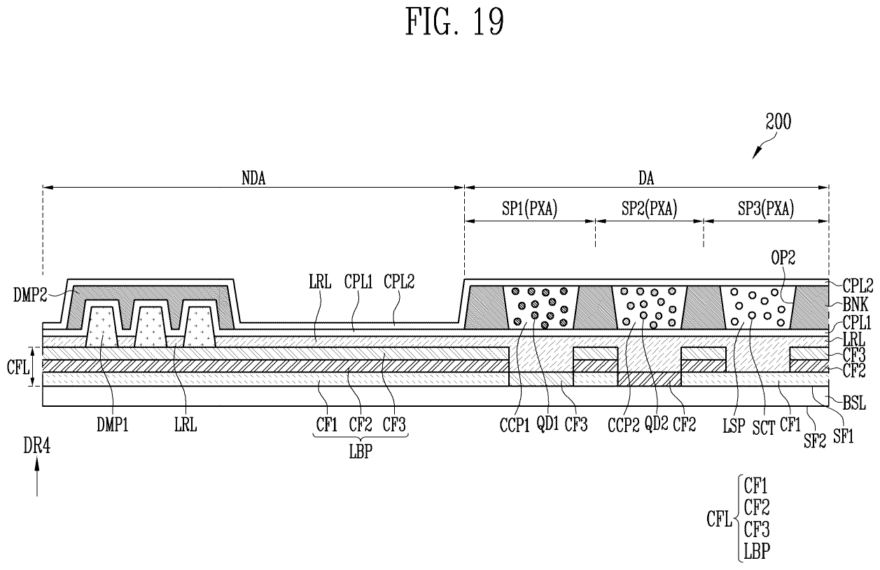

Hereinafter, a method of fabricating the second substrate 200 according to some embodiments will be described in more detail with reference to FIGS. 11 to 19.

FIGS. 11 to 19 are schematic cross-sectional views illustrating a method of forming the second substrate 200 of FIG. 7.

In the embodiments illustrated and described with respect to FIGS. 11 to 19, there is illustrated the case where the steps of fabricating the second substrate 200 are sequentially performed according to the sectional views, but without departing from the spirit and scope of embodiments according to the present disclosure, some steps illustrated as being sequentially performed may be simultaneously or concurrently performed, the sequence of the steps may be changed, some steps may be skipped, or an additional step may be further included between the steps.

The description with reference to FIGS. 11 to 19 will be focused on differences from the above-mentioned embodiments so as to avoid redundant description. Furthermore, in FIGS. 11 to 19, a direction in which the second surface SF2 of the base layer BSL is positioned at a lower portion and the first surface SF1 of the base layer BSL is positioned at an upper portion in a cross-sectional view is defined as a fourth direction DR4.

Referring to FIGS. 7 and 11, the first color filter CF1 is formed on the first surface SF1 of the base layer BSL. The first color filter CF1 may be a blue color filter.

The first color filter CF1 may be formed on the overall area of the first surface SF1 of the base layer BSL in the non-display area NDA. The first color filter CF1 may be formed on the first surface SF1 of the base layer BSL to correspond to the non-emission area (refer to “NEA” of FIG. 5) and the third emission area (refer to “EMA3” of FIG. 5) in the display area DA.

Referring to FIGS. 7, 11, and 12, the second color filter CF2 is formed on the first color filter CF1. The second color filter CF2 may be a red color filter.

The second color filter CF2 may be formed on the overall surface of the first color filter CF1 in the non-display area NDA. The second color filter CF2 may be formed on the first color filter CF1 of the non-emission area NEA in the display area DA. Furthermore, the second color filter CF2 may be formed on the first surface SF1 of the base layer BSL to correspond to the second emission area (refer to “EMA2” of FIG. 5) in the display area DA.

Referring to FIGS. 7 and 11 to 13, the third color filter CF3 is formed on the second color filter CF2. The third color filter CF3 may be a green color filter.

The third color filter CF3 may be formed on the overall surface of the second color filter CF2 in the non-display area NDA. The third color filter CF3 may be formed on the second color filter CF2 of the non-emission area NEA in the display area DA. Furthermore, the third color filter CF3 may be formed on the first surface SF1 of the base layer BSL to correspond to the first emission area (refer to “EMA1” of FIG. 5) in the display area DA.

The first color filter CF1, the second color filter CF2, and the third color filter CF3 that are arranged to overlap each other in the non-display area NDA and the non-emission area NEA may be used as the light blocking pattern LBP. The first color filter CF1, the second color filter CF2, the third color filter CF3, and the light blocking pattern LBP may constitute the color filter layer CFL.

Referring to FIGS. 7 and 11 to 14, the first dummy pattern DMP1 is formed on the light blocking pattern LBP in the non-display area NDA. The first dummy patterns DMP1 that are adjacent to each other may be arranged to be spaced apart from each other. The first dummy pattern DMP1 may be formed through a photolithography process using a mask. The first dummy pattern DMP1 may be configured of an organic layer (or an organic insulating layer) including organic material including titanium dioxide in the form of nanoparticles. The first dummy pattern DMP1 may have a shape protruding in the fourth direction DR4. In other words, the first dummy pattern DMP1 may have a shape protruding from the light blocking pattern LBP in the direction toward the sealing component 300.

Referring to FIGS. 7 and 11 to 15, the low-refractive layer LRL is formed on the light blocking pattern LBP and the color filter layer CFL. For example, the low-refractive layer LRL may be formed through a curing process or the like after being applied on the light blocking pattern LBP and the color filter layer CFL through an inkjet printing or spin coating method, or the like.

In the non-display area NDA, the low-refractive layer LRL may include discontinuity portions separated from each other by the first dummy pattern DMP1. Because the coating thickness of the low-refractive layer LRL relative to the height of the first dummy pattern DMP1 is sufficiently small (or thin), the low-refractive layer LRL can be interrupted by the first dummy pattern DMP1 in the non-display area NDA. In the non-display area NDA, the low-refractive layer LRL may be formed on the light blocking pattern LBP between the first dummy patterns DMP1 adjacent to each other.

Referring to FIGS. 7 and 11 to 16, the first capping layer CPL1 is formed on the low-refractive layer LRL and the first dummy pattern DMP1 by a chemical vapor deposition method or the like. The first capping layer CPL1 may be configured of an inorganic layer (or an inorganic insulating layer) including inorganic material. For example, the first capping layer CPL1 may include at least one of silicon nitride (SiNₓ), silicon oxide (SiOₓ), silicon oxynitride (SiOₓN_{y}), or aluminum oxide (AlOₓ). However, the material of the first capping layer CPL1 is not limited to the foregoing embodiments.

Referring to FIGS. 7 and 11 to 17, the bank BNK and the second dummy pattern DMP2 are simultaneously or concurrently or sequentially formed on the first capping layer CPL1. The bank BNK and the second dummy pattern DMP2 may have the same material, and may be provided in the same layer. The bank BNK and the second dummy pattern DMP2 may have a planar upper surface with respect to the fourth direction DR4.

The bank BNK may be patterned to include a plurality of second openings OP2 in the display area DA. The second dummy pattern DMP2 may be partially located on the first capping layer CPL1 to correspond to the first dummy pattern DMP1. The second dummy pattern DMP2 may be provided in a shape in which a stepped portion STP of the first capping layer CPL1 positioned on the low-refractive layer LRL between the adjacent first dummy patterns DMP1 is filled with the second dummy pattern DMP2, but the present disclosure is not limited thereto.

Referring to FIGS. 7 and 11 to 18, the first color conversion pattern CCP1 is formed in at least one second opening OP2 among the second openings OP2 of the bank BNK. The second color conversion pattern CCP2 is formed in another second opening OP2 among the second openings OP2. The light scattering pattern LSP is formed in another second opening OP2 among the second openings OP2.

For example, the first color conversion pattern CCP1 is formed in the corresponding second opening OP2 of the bank BNK by an inkjet printing method or the like. After the first color conversion pattern CCP1 is formed, the second color conversion pattern CCP2 is formed in the corresponding second opening OP2 of the bank BNK by the inkjet printing method or the like. After the second color conversion pattern CCP2 is formed, the light scattering pattern LSP is formed in the corresponding second opening OP2 of the bank BNK by the inkjet printing method or through a photolithography process using a mask. Here, the sequence of fabricating the first color conversion pattern CCP1, the second color conversion pattern CCP2, and the light scattering pattern LSP is not limited to the aforementioned embodiments. According to some embodiments, the light scattering pattern LSP may be first formed, followed by formation of the first color conversion pattern CCP1 after the formation of the light scattering pattern LSP, and thereafter, the second color conversion pattern CCP2 may be formed after the formation of the first color conversion pattern CCP1.

Referring to FIGS. 7 and 11 to 19, the second capping layer CPL2 may be formed over the display area DA and the non-display area NDA by a chemical vapor deposition method or the like. The second capping layer CPL2 may be formed on the first capping layer CPL1 and the second dummy pattern DMP2 in the non-display area NDA. Furthermore, the second capping layer CPL2 may be formed on the bank BNK, the first and second color conversion patterns CCP1 and CCP2, and the light scattering pattern LSP in the display area DA.

The second capping layer CPL2 may be an inorganic layer (or an inorganic insulating layer) including inorganic material. For example, the second capping layer CPL2 may include at least one of silicon nitride (SiNₓ), silicon oxide (SiOₓ), silicon oxynitride (SiOₓN_{y}), or aluminum oxide (AlOₓ). However, the material of the second capping layer CPL2 is not limited to the foregoing embodiments.

The first substrate 100 including the display element layer DPL may be formed. The second substrate 200 facing the first substrate 100 may be formed. The second substrate 200 having the aforementioned configuration may be coupled to the first substrate 100 using the sealing component (refer to “300” of FIG. 7). Here, the filling layer (refer to “400” of FIG. 7) may be formed in the display area DA between the first substrate 100 and the second substrate 200.

According to some embodiments, a structure (or a first dummy pattern) may be located on a sealing component between a first substrate (or a lower substrate) and a second substrate (or an upper substrate) so that a low-refractive layer in a non-display area is interrupted. Consequently, external water, oxygen, or the like may be reduced or prevented from being drawn from the non-display area into a display area through the low-refractive layer. As a result, a display device having relatively improved reliability, and a method of fabricating the display device may be provided.

The effects of the present disclosure are not limited by the foregoing, and other various effects are anticipated herein.

While aspects of some embodiments of the present disclosure have been described above, those skilled in the art will appreciate that various modifications, additions and substitutions are possible, without departing from the spirit and scope of embodiments according to the present disclosure.

Therefore, the embodiments disclosed in this specification are only for illustrative purposes rather than limiting the technical spirit of the present disclosure. The scope of embodiments according to the present disclosure are defined by the accompanying claims, and their equivalents.

What is claimed is:

1. A display device, comprising:
a first substrate including a display element layer;
a second substrate facing the first substrate; and
a sealing component between the first substrate and the second substrate,
wherein the second substrate comprises:
a base layer including a display area overlapping the display element layer, and a non-display area enclosing the display area;
a light blocking pattern in the non-display area of the base layer;
a first dummy pattern between the light blocking pattern and the sealing component in the non-display area;
a low-refractive layer in the non-display area and the display area, and interrupted by the first dummy pattern; and
a second dummy pattern covering the first dummy pattern in the non-display area.

2. The display device according to claim 1, wherein the first dummy pattern includes an organic material.

3. The display device according to claim 1, wherein the first dummy pattern has a shape protruding from the light blocking pattern in a direction toward the sealing component.

4. The display device according to claim 1, wherein the first dummy pattern comprises a plurality of first dummy patterns.

5. The display device according to claim 4, wherein the low-refractive layer is between the first dummy patterns adjacent to each other in the non-display area.

6. The display device according to claim 1, wherein the second substrate further comprises:
a bank in the display area, and including a plurality of openings therein; and
a color conversion pattern in at least one opening of the openings, and a light scattering pattern in another opening among the openings,
wherein the second dummy pattern includes a material identical to the bank.

7. The display device according to claim 6, wherein the first dummy pattern includes a material identical to the light scattering pattern.

8. The display device according to claim 7, wherein each of the first dummy pattern and the light scattering pattern includes base resin in which scattering particles are dispersed.

9. The display device according to claim 6, wherein the first dummy pattern is in a layer different from the light scattering pattern.

10. The display device according to claim 6, wherein the second substrate further comprises:
a first capping layer on the first dummy pattern and the low-refractive layer in a direction toward the sealing component; and
a second capping layer on the second dummy pattern, the first capping layer, and the bank in the direction toward the sealing component.

11. The display device according to claim 10, wherein each of the first capping layer and the second capping layer includes an inorganic material.

12. The display device according to claim 10, wherein the base layer includes a dummy pixel area adjacent to the display area and corresponding to at least one area of the non-display area.

13. The display device according to claim 1,
wherein the second substrate further comprises a color filter layer in the display area and the non-display area and between the low-refractive layer and the base layer, and
wherein the color filter layer comprises a first color filter, a second color filter, and a third color filter.

14. The display device according to claim 13, wherein in the non-display area, the first color filter, the second color filter, and the third color filter are stacked on top of one another to form the light blocking pattern.

15. The display device according to claim 1, further comprising a filling layer between the first substrate and the second substrate,
wherein the filling layer extends from the display area to the non-display area and has at least a portion covered with the sealing component.

16. The display device according to claim 1, wherein the display element layer comprises:
a transistor on a substrate, and corresponding to the display area;
a light emitting element on the transistor, and including an emission layer; and
an encapsulation layer on the light emitting element.

17. A method of fabricating a display device, comprising:
forming a first substrate including a display element layer;
forming a second substrate facing the first substrate; and
bonding the first substrate and the second substrate to each other by a sealing component,
wherein the second substrate comprises:
a base layer including a display area overlapping the display element layer, and a non-display area enclosing the display area;
a light blocking pattern in the non-display area of the base layer;
a first dummy pattern between the light blocking pattern and the sealing component in the non-display area;
a low-refractive layer in the non-display area and the display area, and interrupted by the first dummy pattern;
a bank in the display area, and including a plurality of openings therein;
an optical layer in the display area, and including a color conversion pattern in at least one opening among the openings, and a light scattering pattern in another opening among the openings; and
a second dummy pattern covering the first dummy pattern in the non-display area.

18. The method according to claim 17,
wherein the first dummy pattern includes an organic material, and
wherein the second dummy pattern includes a material identical to the bank.

19. The method according to claim 17, wherein forming the second substrate comprises:
forming a first color filter, a second color filter, and a third color filter on one surface of the base layer in the display area, and forming the light blocking pattern on the one surface of the base layer in the non-display area;
forming the first dummy pattern on the light blocking pattern;
forming the low-refractive layer on the first dummy pattern and the first to the third color filters;
forming a first capping layer on the low-refractive layer and the first dummy pattern;
forming the second dummy pattern on the first capping layer on the first dummy pattern, and forming the bank on the first capping layer in the display area;
respectively forming the color conversion pattern and the light scattering pattern in the corresponding openings among the openings of the bank; and
forming a second capping layer on the second dummy pattern, the color conversion pattern, the light scattering pattern, and the first capping layer.
